(19) United States
(12) Patent Application Publication
(10) Pub. No.: US 2014/0214191 A1
(43) Pub. Date: Jul. 31, 2014

(54) Adaptive Integrated Circuit to Optimize Power and Performance Across Process Variations

(71) Applicant: BROADCOM CORPORATION, Irvine, CA (US)

(72) Inventors: Sandeep MIRCHANDANI, Palo Alto, CA (US); John REDMOND, Escondido, CA (US); Sushma HONNAVARA PRASAD, Sunnyvale, CA (US); Tim SIPPEL, Portland, OR (US); Chi-Jung PENG, Cupertino, CA (US)

(73) Assignee: Broadcom Corporation, Irvine, CA (US)

(21) Appl. No.: 13/850,533

(22) Filed: Mar. 26, 2013

Related U.S. Application Data
(60) Provisional application No. 61/758,922, filed on Jan. 31, 2013.

(51) Int. Cl. H01L 21/66

(52) U.S. Cl. CPC H01L 22/14
USPC 700/97; 702/64

(57) ABSTRACT

An integrated circuit is disclosed that measures and/or monitors a substrate parameter. An actual value of the substrate parameter can vary from its expected value as a result of characteristics of the integrated circuit and/or characteristics of an environment surrounding the integrated circuit. The integrated circuit classifies the semiconductor substrate upon which it is fabricated as being a fast semiconductor substrate or a slow semiconductor substrate based upon the substrate parameter. The integrated circuit operates in a fast-substrate mode of operation when the semiconductor substrate is classified as being a fast semiconductor substrate to adjust an operational parameter to compensate for the fast semiconductor substrate or in a slow-substrate mode of operation when the semiconductor substrate is classified as being a slow semiconductor substrate to adjust the operational parameter to compensate for the slow semiconductor substrate.

### CROSS-REFERENCE TO RELATED APPLICATIONS

The present application claims the benefit of U.S. Provisional Patent Appl. No. 61/758,922, filed Jan. 31, 2013, which is incorporated herein by reference in its entirety.

### BACKGROUND

1. Field of Disclosure

The present disclosure generally relates to compensating for process variation in semiconductor fabrication and specifically to an adaptive integrated circuit that adjusts an operational parameter to, achieve optimal power consumption while maximizing performance in complementary metal oxide (CMOS) circuits in the presence of process variations.

2. Related Art

An integrated circuit layout is the representation of one or more integrated circuits in terms of planar geometric shapes which correspond to the patterns of metal, oxide, or semiconductor layers that form components of the integrated circuit. These integrated circuit layouts are translated, by integrated circuit designers into an industry standard format which are translated into an industry standard format which is thereafter sent to a semiconductor foundry for manufacture onto the semiconductor substrate. The semiconductor foundry tailors its photolithographic process for fabrication using the integrated circuit layouts to fabricate the one or more integrated circuits onto the semiconductor substrate.

The various processes used by the semiconductor foundry to fabricate the one or more integrated circuits onto the semiconductor substrate include deposition, removal, patterning, and modification. The deposition is a process used by the semiconductor foundry to grow, coat, or otherwise transfer a material onto the semiconductor substrate and can include physical vapor deposition (PVD), chemical vapor deposition (CVD), electrochemical deposition (ECD), and/or molecular beam epitaxy (MBE) to provide some examples. The removal is a process used by the semiconductor foundry to remove material from the semiconductor substrate and can include wet etching, dry etching, and/or chemical-mechanical planarization (CMP) to provide some examples. The patterning, often referred to as lithography, is a process used by the semiconductor foundry to shape or alter material of the semiconductor substrate to form the planar geometric shapes of the integrated circuit. The modification of electrical properties is a process used by the semiconductor foundry to shape or alter physical, electrical, and/or chemical properties of material of the semiconductor substrate, typically, by ion implantation. The semiconductor substrate used to fabricate the one or more integrated circuits is typically part of a semiconductor wafer. The semiconductor foundry can fabricate multiple of the one or more integrated circuits as well as other integrated circuits onto the semiconductor wafer.

Minor uncontrollable discrepancies within and/or between these various processes, referred to as semiconductor process variation, can cause some of the integrated circuits within the semiconductor wafer, or between semiconductor wafers, to operate unexpectedly. The semiconductor process variation represents a variation within an attribute of the integrated circuit, such as a length, a width, and/or an oxide thickness of transistors to provide some examples, which naturally occurs when the integrated circuit is fabricated onto the semiconductor substrate. These semiconductor process variations are typically measured and quantified by the semiconductor foundry as manufacturing tolerances. In addition to the manufacturing tolerances, environmental conditions, such as humidity, temperature or any other environmental condition, surrounding the integrated circuit can also effect the performance of various integrated circuits. For example, the integrated circuit may operate at a slower speed in a cold environment, the operating speed may can increase as the temperature of the environment and/or the integrated circuit increases.

### BRIEF DESCRIPTION OF THE DRAWINGS/FIGURES

The present disclosure is described with reference to the accompanying drawings. In the drawings, like reference numbers indicate identical or functionally similar elements. Additionally, the left most digit(s) of a reference number identifies the drawing in which the reference number first appears.

FIG. 1 graphically illustrates a normal distribution of performance of various integrated circuits that are fabricated by a semiconductor foundry according to an exemplary embodiment of the present disclosure;

FIG. 2 illustrates a block diagram of a first adaptive integrated circuit according to an exemplary embodiment of the present disclosure;

FIGS. 3A and 3B illustrate a first exemplary operation of the first adaptive integrated circuit according to an exemplary embodiment of the present disclosure;

FIG. 4 illustrates a block diagram of a second adaptive integrated circuit according to an exemplary embodiment of the present disclosure; and

FIG. 5 illustrates a block diagram of an exemplary process monitor module that can be implemented as part of the first or the second adaptive integrated circuits according to an exemplary embodiment of the present disclosure.

The present disclosure will now be described with reference to the accompanying drawings. In the drawings, like reference numbers generally indicate identical, functionally similar, and/or structurally similar elements. The drawing in which an element first appears is indicated by the leftmost digit(s) in the reference number.

### DETAILED DESCRIPTION OF THE DISCLOSURE

The following Detailed Description refers to accompanying drawings to illustrate exemplary embodiments consistent with the disclosure. References in the Detailed Description to “one exemplary embodiment,” “an exemplary embodiment,” “an example exemplary embodiment,” etc., indicate that the exemplary embodiment described can include a particular feature, structure, or characteristic, but every exemplary embodiment does not necessarily include the particular feature, structure, or characteristic. Moreover, such phrases are not necessarily referring to the same exemplary embodiment. Further, when a particular feature, structure, or characteristic is described in connection with an exemplary embodiment, it is within the knowledge of those skilled in the relevant art(s) to affect such feature, structure, or characteristic in connection with other exemplary embodiments whether or not explicitly described.

The exemplary embodiments described herein are provided for illustrative purposes, and are not limiting. Other exemplary embodiments are possible, and modifications can be made to the exemplary embodiments within the spirit and scope of the disclosure. Therefore, the Detailed Description is not meant to limit the disclosure. Rather, the scope of the disclosure is defined only in accordance with the following claims and their equivalents.

Embodiments of the disclosure can be implemented in hardware, firmware, software, or any combination thereof. Embodiments of the disclosure can also be implemented as instructions stored on a machine-readable medium, which can be read and executed by one or more processors. The machine-readable medium can include any mechanism for storing or transmitting information in a form readable by a machine (e.g., a computing device). For example, a machine-readable medium can include a non-transitory machine-readable medium such as read only memory (ROM); random access memory (RAM); magnetic disk storage media; optical storage media; flash memory devices; and others. As another example, the machine-readable medium can include a transitory machine-readable medium such as an electrical, optical, acoustical, or other form of a propagated signal (e.g., a carrier wave, an infrared signal, a digital signal, etc.). Further, firmware, software, routines, instructions can be described herein as performing certain actions. However, it should be appreciated that such descriptions are merely for convenience and that such actions in fact result from computing devices, processors, controllers, or other devices executing the firmware, software, routines, instructions, etc.

The following Detailed Description of the exemplary embodiments will so fully reveal the general nature of the disclosure that others can, by applying knowledge of those skilled in relevant art(s), readily modify and/or adapt for various applications such exemplary embodiments, without undue experimentation, and without departing from the spirit and scope of the disclosure. Therefore, such adaptations and modifications are intended to be within the meaning and plurality of equivalents of the exemplary embodiments based upon the teaching and guidance presented herein. It is to be understood that the phraseology or terminology herein is for the purpose of description and not of limitation, such that the terminology or phraseology of the present specification is to be interpreted by those skilled in relevant art(s) in light of the teachings herein.

For purposes of this discussion, the term “module” shall be understood to include at least one of software, firmware, and hardware (such as one or more circuits, microchips, or devices, or any combination thereof), and any combination thereof In addition, it will be understood that each module can include one, or more than one, component within an actual device, and each component that forms a part of the described module can function either cooperatively or independently of any other component forming a part of the module. Conversely, multiple modules described herein can represent a single component within an actual device. Further, components within a module can be in a single device or distributed among multiple devices in a wired or wireless manner.

Semiconductor Process Variation

As discussed above, minor uncontrollable discrepancies within and/or between these various processes, referred to as semiconductor process variation, can cause some of the integrated circuits within the semiconductor wafer, or between semiconductor wafers, to operate unexpectedly. The semiconductor process variation represents a variation within an attribute of the integrated circuit, such as a length, a width, and/or an oxide thickness of transistors to provide some examples, which naturally occurs when the integrated circuit is fabricated onto the semiconductor substrate. These semiconductor process variations are typically measured and quantified by the semiconductor foundry as manufacturing tolerances. The effect of the manufacturing tolerances on performance of various integrated circuits can be statistically approximated using a normal, or Gaussian, distribution; however, those skilled in the relevant art(s) will recognize that other distributions can be used to approximate the performance of the various integrated circuits without departing from the sprit and scope of the present invention.

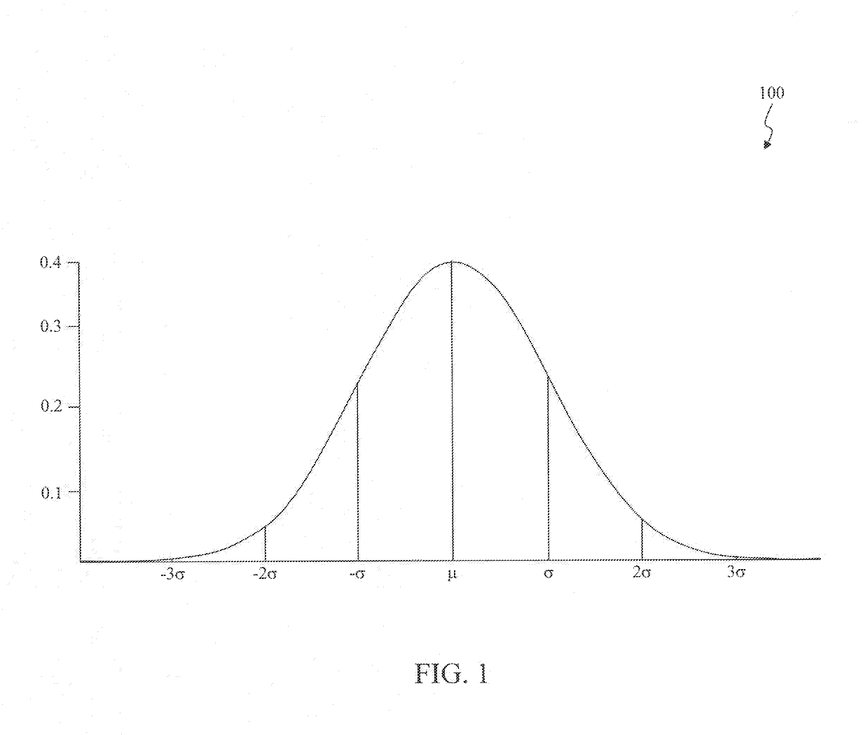

FIG. 1 graphically illustrates a normal distribution of performance of various integrated circuits that are fabricated by a semiconductor foundry according to an exemplary embodiment of the present disclosure. In probability theory, a normal distribution 100 is a continuous probability distribution, defined on the entire real line, which has a bell-shaped probability density function, known as the Gaussian function. The normal distribution 100 is commonly encountered in practice, and is used throughout statistics, the natural sciences, and the social sciences as a simple model for complex phenomena. Additionally, in statistics and probability theory, a standard deviation σ represents a variation or “dispersion” that exists around the mean μ. A low standard deviation indicates that the data points tend to be very close to the mean μ; while a high standard deviation indicates that the data points are spread out over a large range of values.

For example, as shown in FIG. 1, if the mean μ represents an integrated circuit that is fabricated by the semiconductor foundry which operates as a speed as designed or expected, then approximately 68.27% of the integrated circuits that are fabricated by the semiconductor foundry will operate within one standard deviation of the designed or expected operational speed. Approximately half of the integrated circuits within the 68.27% will be within a standard deviation of −σ, which indicates that these integrated circuits operate slower, referred to as slow-speed integrated circuits, than as designed or expected. Likewise, approximately half of the integrated circuits within the 68.27% will be within a standard deviation of σ, which indicates that these integrated circuits operate faster, referred to as fast-speed integrated circuits, than as designed or expected.

Similarly, approximately 95.45% of the integrated circuits that are fabricated by the semiconductor foundry will operate within two standard deviations 2σ of the designed or expected operational speed. Approximately half of the integrated circuits within the 95.45% will be within a standard deviation of −2σ, which indicates that these integrated circuits will be slow-speed integrated circuits. Those integrated circuits whose operational speed are between the standard deviation of −σ and the standard deviation of −2σ operate slower than those integrated circuits whose operational speed are between the standard deviation of −σ and the mean μ. Likewise, approximately half of the integrated circuits within the 95.45% will be within a standard deviation of 2σ, which indicates that these integrated circuits will be fast-speed integrated circuits. Those integrated circuits whose operational speed are between the standard deviation of σ and the standard deviation of 2σ operate faster than those integrated circuits whose operational speed are between the standard deviation of σ and the mean μ.

Likewise, approximately 99.73% of the integrated circuits that are fabricated by the semiconductor foundry will operate within three standard deviations 3σ of the designed or expected operational speed. Approximately half of the integrated circuits within the 99.73% will be within a standard deviation of −3σ, which indicates that these integrated circuits will be slow-speed integrated circuits. Those integrated circuits whose operational speed are between the standard deviation of −3σ and the standard deviation of −2σ operate slower than those integrated circuits whose operational speed are between the standard deviation of −2σ and standard deviation of −σ. Likewise, approximately half of the integrated circuits within the 99.73% will be within a standard deviation of 3σ, which indicates that these integrated circuits will be fast-speed integrated circuits. Those integrated circuits whose operational speed are between the standard deviation of 2σ and the standard deviation of 3σ operate faster than those integrated circuits whose operational speed are between the standard deviation of σ and standard deviation of 2σ.

Overview

The present disclosure provides for an integrated circuit that measures and/or monitors a substrate parameter. An actual value of the substrate parameter can vary from its expected value as a result of characteristics of the integrated circuit, such as manufacturing tolerances or temperature to provide some examples, and/or characteristics of an environment surrounding the integrated circuit, such as temperature and/or humidity to provide some examples. In some situations, the characteristics of the integrated circuit and/or the characteristics of the environment are not constant. Rather, these characteristics can vary or fluctuate over time.

The integrated circuit classifies a semiconductor substrate upon which it is fabricated as being a fast semiconductor substrate or a slow semiconductor substrate based upon the substrate parameter. The integrated circuit operates in a fast-substrate mode of operation when the semiconductor substrate is classified as being a fast semiconductor substrate to adjust an operational parameter, such as operational speed and/or leakage current to provide some examples, to compensate for the fast semiconductor substrate, or in a slow-substrate mode of operation when the semiconductor substrate is classified as being a slow semiconductor substrate to adjust the operational parameter to compensate for the slow semiconductor substrate. In an exemplary embodiment, the integrated circuit can be characterized as having slower speed and lesser leakage current when operating in the slow-substrate mode of operation as compared to the fast-substrate mode of operation. However, the increased operational speed of the slow semiconductor substrate can compensate for this decrease in speed when operating in the slow-substrate mode of operation.

A First Adaptive Integrated Circuit

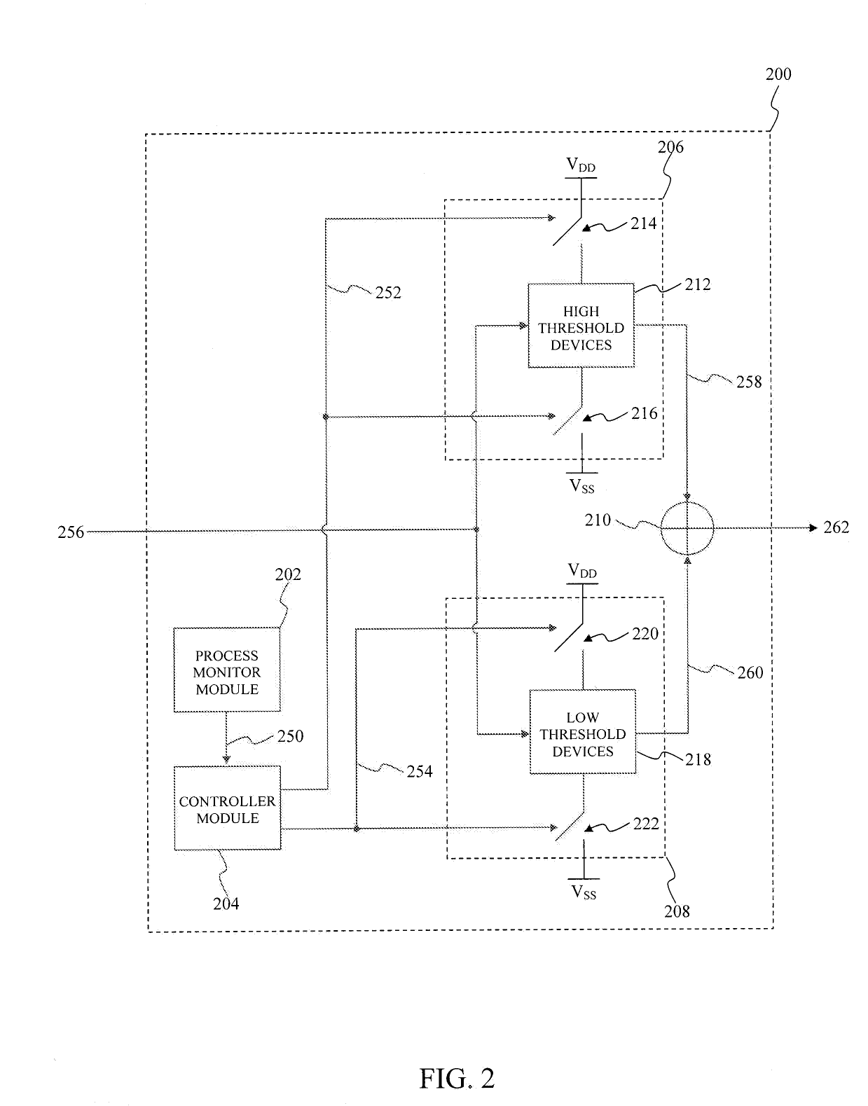

FIG. 2 illustrates a block diagram of a first adaptive integrated circuit according to an exemplary embodiment of the present disclosure. An adaptive integrated circuit 200 is fabricated onto a semiconductor substrate. The adaptive integrated circuit 200 classifies the semiconductor substrate upon which it is fabricated as being a fast semiconductor substrate or a slow semiconductor substrate by monitoring a substrate parameter. The adaptive integrated circuit 200 operates in a fast-substrate mode of operation using high voltage threshold semiconductor devices to decrease its operational speed and its leakage current when the semiconductor substrate is classified as being a fast semiconductor substrate. Otherwise, the adaptive integrated circuit 200 operates in a slow-substrate mode of operation using low voltage threshold semiconductor devices to increase its operational speed with increase in leakage current when the semiconductor substrate is classified as being a slow speed semiconductor substrate. The adaptive integrated circuit 200 includes a process monitor module 202, a controller module 204, a fast semiconductor substrate module 206, a slow semiconductor substrate module 208, and a summation module 210.

The process monitor module 202 measures and/or monitors a substrate parameter of the adaptive integrated circuit 200 to provide a substrate parameter 250. The substrate parameter can include an indication of an operational speed of the adaptive integrated circuit 200, an indication of an operating voltage and/or current of the adaptive integrated circuit 200, an indication of a transconductance of the semiconductor substrate, an indication of a resistivity per unit area of the semiconductor substrate, an indication of a threshold voltage for semiconductor devices constructed on the semiconductor substrate, an indication of a temperature of the adaptive integrated circuit 200, and/or an indication of any other suitable operation parameter that will be apparent to those skilled in the relevant art(s) without departing from the spirit and scope of the present disclosure. An actual value of the substrate parameter can vary front its expected value as a result of characteristics of the adaptive integrated circuit 200, such as manufacturing tolerances or temperature to provide some examples, and/or characteristics of an environment surrounding the integrated circuit, such as temperature and/or humidity to provide some examples. In some situations, the characteristics of the adaptive integrated circuit 200 and/or the characteristics of the environment are not constant. Rather, these characteristics can vary or fluctuate over time.

The controller module 204 classifies the semiconductor substrate upon which it is fabricated as being a fast semiconductor substrate or a slow semiconductor substrate based upon the substrate parameter 250. In an exemplary embodiment, the controller module 204 determines which expected substrate parameter from among multiple expected substrate parameters corresponds to an actual value of the substrate parameter 250. Each of the multiple expected substrate parameters represent an expected value, or expected range, for the substrate parameter 250 that corresponds to one or more standard deviations σ of an operational speed of the semiconductor substrate from an expected value μ for the operational speed. The controller module 204 selects the expected substrate parameter from among the multiple expected substrate parameters which is closest to the actual value of the substrate parameter 250. For example, as shown in Table 1 below, the controller module 204 compares the actual value of the substrate parameter 250 to substrate parameters p₋₃ through p₃. In this example, the controller module 204 determines which of the substrate parameters p₋₃ through p₃ is closest to the actual value of the substrate parameter 250.

TABLE 1
Exemplary Operation of the Controller Module

| STANDARD DEVIATIONS FROM | EXPECTED SUBSTRATE |
|---|---|
| EXPECTED PARAMETER | PARAMETER |
| −3σ | p₋₃ |
| −2σ | p₋₂ |
| −σ | p₋₁ |
| μ | p₀ |
| σ | p₁ |
| 2σ | p₂ |
| 3σ | p₃ |

Next, the controller module 204 determines a standard deviation σ of the operational speed of the semiconductor substrate from its expected value μ. The controller module 204 determines the operational speed of the semiconductor substrate by mapping the expected substrate parameter to a corresponding standard deviation σ. From the example above, as shown in Table 1 above, the controller module 204 determines the operational speed of the semiconductor substrate is one standard deviation from its expected value μ when the actual value of the substrate parameter 250 is closest to the substrate parameter p₁.

Thereafter, the controller module 204 classifies the semiconductor substrate as being the slow semiconductor substrate when the standard deviation σ is less than zero, as being the fast semiconductor substrate when the standard deviation σ is greater than zero, or as being either the slow or the fast semiconductor substrate when the standard deviation σ is equal to zero. From the example above, as shown in Table 1 above, the controller module 204 classifies the semiconductor substrate as being the slow semiconductor substrate when the standard deviation σ is between standard deviation −3σ and the expected, value μ, as being the fast semiconductor substrate when the standard deviation σ is between the expected value μ and standard deviation 3σ, or as being either the slow or the fast semiconductor substrate when the standard deviation σ is equal to zero. In some situations, it can be beneficial for the controller module 204 to determine the precise number of standard deviations σ that the operational speed of the semiconductor substrate is from its expected value μ.

Slow-Substrate and Fast-Substrate Modes of Operation

When the semiconductor substrate is classified as being the fast semiconductor substrate, the controller module 204 provides a fast-substrate mode control signal 252 to activate the fast semiconductor substrate module 206 and a slow-substrate mode control signal 254 to deactivate the slow semiconductor substrate module 208 to cause the adaptive integrated circuit 200 to operate in the fast-substrate mode of operation. Similarly, when the semiconductor substrate is classified as being the slow semiconductor substrate, the controller module 204 provides the fast-substrate mode control signal 252 to deactivate the fast semiconductor substrate module 206 and the slow-substrate mode control signal 254 to activate the slow semiconductor substrate module 208 to cause the adaptive integrated circuit 200 to operate in the slow-substrate mode of operation.

Alternatively, or in addition to, the controller module 204 can estimate operational processing speed that is needed by the adaptive integrated circuit 200 for processing an input signal 256. For example, the adaptive integrated circuit 200 can be implemented as part of a mobile communication device, such as a mobile telephony device, such as a mobile phone, a mobile computing device, a mobile internet device, a personal digital assistant, a handheld game console, a portable media player, a digital still camera, a digital video camera, a pager, a personal navigation device, a tablet computer, and/or any other suitable communications device that will be apparent to those skilled in the relevant art(s) without departing from the spirit and scope of the present disclosure. In this example, the controller module 204 can determine more operational processing speed is required to process a multimedia data stream, having audio and video components, for playback than is required to process a telephony data stream, having only an audio component, for playback. The adaptive integrated circuit 200 can operate in a fast-operating mode of operation which corresponds to the slow-substrate mode of operation to increase its operational speed and/or its leakage current when a faster operational speed is needed to process the input signal 256. Otherwise, the adaptive integrated circuit 200 operates in a slow-operating mode of operation which corresponds to the fast-substrate mode of operation to decrease its operational speed and/or its leakage current when a slower operational speed can be used to process the input signal 256.

The fast semiconductor substrate module 206 operates upon the input signal 256, such as an analog, discrete, and/or digital signal to provide some examples, to provide an output signal 258 when the adaptive integrated circuit 200 is operating in the fast-substrate mode of operation that corresponds to the fast semiconductor substrate. The fast semiconductor substrate module 206 includes a logic circuit that is formed using high threshold voltage semiconductor devices 212 and first and second activation switches 214 and 216. The logic circuit can be configured and arranged to provide one or more suitable digital signal processing functions and/or one or more suitable analog signal processing functions. The digital signal processing functions can include one or more Boolean logic functions, such as AND, OR, XOR, XNOR, or NOT to provide some examples, or one or more storage functions, such as a flip-flop or a latch to provide some examples. The simplest implementation of the digital signal processing functions is a direct representation of the elemental AND, OR, XOR, XNOR, or NOT Boolean logic functions, although implementations of much greater complexity can be used.

This logic circuit is formed using high threshold voltage semiconductor devices that are characterized as being slow-speed and having low leakage current when compared, to low threshold voltage semiconductor devices. Although an operational speed of the adaptive integrated circuit 200 is reduced when using the high threshold voltage semiconductor devices when compared to using the low threshold voltage semiconductor devices, the fast semiconductor substrate can compensate for this reduction in operational speed such that the adaptive integrated circuit 200 operates as designed or expected, or within a designed or an expected range. Additionally, this reduction in the leakage current of the threshold voltage semiconductor devices allows the adaptive integrated circuit 200 to operate for a longer duration than if only the low threshold voltage semiconductor devices were used.

The first and second activation switches 214 and 216 couple and/or decouple the fast semiconductor substrate module 206 to a first supply potential, such as V_{DD} to provide an example, and a second supply potential, such as V_{SS} or ground to provide some examples, respectively, to activate and/or deactivate the fast semiconductor substrate module 206. For example, the fast-substrate mode control signal 252 activates the first and second activation switches 214 and 216 when the adaptive integrated circuit 200 is operating in the fast-substrate mode of operation to couple the fast semiconductor substrate module 206 to the first supply potential and the second supply potential. This coupling of the logic circuit that is formed using high threshold voltage semiconductor devices 212 to the first supply potential and the second supply potential activates the fast semiconductor substrate module 206 to allow the fast semiconductor substrate module 206 to operate upon the input signal 256. As another example, the fast-substrate mode control signal 252 deactivates the first and second activation switches 214 and 216 when the adaptive integrated circuit 200 is operating in the slow-substrate mode of operation to decouple the fast semiconductor substrate module 206 from the first supply potential and the second supply potential.

The slow semiconductor substrate module 208 operates upon the input signal 256 to provide an output signal 258 when the adaptive integrated circuit 200 is operating in the slow-substrate mode of operation that corresponds to the slow semiconductor substrate. The slow semiconductor substrate module 208 includes a logic circuit that is formed using low threshold voltage semiconductor devices 218 and first and second activation switches 220 and 222. The logic circuit is formed using the low threshold voltage semiconductor devices 218 is configured and arranged to perform substantially similar digital signal processing functions and/or analog signal processing as the logic circuit that is formed using high threshold voltage semiconductor devices 212; however, the logic circuit that is formed using the low threshold voltage semiconductor devices 218 is implemented using low threshold voltage semiconductor devices rather than the high threshold voltage semiconductor devices. The low threshold voltage semiconductor devices are characterized as being high speed and having high leakage current when compared to high threshold voltage semiconductor devices. The operational speed of the adaptive integrated circuit 200 is increased when using the low threshold voltage semiconductor devices when compared to using the high threshold voltage semiconductor devices which compensates for the slow semiconductor substrate. However, the low threshold voltage semiconductor devices increase the leakage current which cause the adaptive integrated circuit 200 to operate for a shorter duration than if only the high threshold voltage semiconductor devices were used.

The first and second activation switches 220 and 222 couple and/or decouple the slow semiconductor substrate module 208 to the first supply potential and the second supply potential, respectively, to activate and/or deactivate the slow semiconductor substrate module 208. For example, the slow-substrate mode control signal 254 activates the first and second activation switches 220 and 222 when the adaptive integrated circuit 200 is operating in the slow-substrate mode of operation to couple the slow semiconductor substrate module 208 to the first supply potential and the second supply potential. This coupling of the logic circuit that is formed using low threshold voltage semiconductor devices 218 to the first supply potential and the second supply potential activates the slow semiconductor substrate module 208 to allow the slow semiconductor substrate module 208 to operate upon the input signal 256. As another example, the slow-substrate mode control signal 254 deactivates the first and second activation switches 220 and 222 when the adaptive integrated circuit 200 is operating in the fast-substrate mode of operation to decouple the slow semiconductor substrate module 208 from the first supply potential and the second supply potential.

The summation module 210 combines the output signal 258 and the output signal 260 to provide an output signal 262.

Hyper-Speed Mode of Operation

Additionally, the controller module 204 can provide the fast-substrate mode control signal 252 and the slow-substrate mode control signal 254 to substantially simultaneously activate the fast semiconductor substrate module 206 and the slow semiconductor substrate module 208, respectively, to cause the adaptive integrated circuit 200 to operate in a hyper-speed mode of operation. When in the hyper-speed mode of operation, the operational speed of the adaptive integrated circuit 200 is faster than either the fast-substrate mode of operation or the slow-substrate mode of operation; however, the hyper-speed mode of operation increases the leakage current which causes the adaptive integrated circuit 200 to operate for a shorter duration than if either the fast-substrate mode of operation or the slow-substrate mode of operation is operated alone.

Stop Mode of Operation

Further, the controller module 204 can provide the fast-substrate mode control signal 252 and the slow-substrate mode control signal 254 to substantially simultaneously deactivate the fast semiconductor substrate module 206 and the slow semiconductor substrate module 208, respectively, to cause the adaptive integrated circuit 200 to operate in the stop mode of operation. When in the stop mode of operation, neither the fast semiconductor substrate module 206 nor the slow semiconductor substrate module 208 operates upon the input signal 256.

Another Exemplary Operation of the First Adaptive Integrated Circuit

The controller module 204 can additionally cause the adaptive integrated circuit 200 to operate in the slow-substrate mode of operation or the fast-substrate mode of operation such that an operational parameter, such as operational speed to provide an example, of the adaptive integrated circuit 200 meets or exceeds a specified operational parameter.

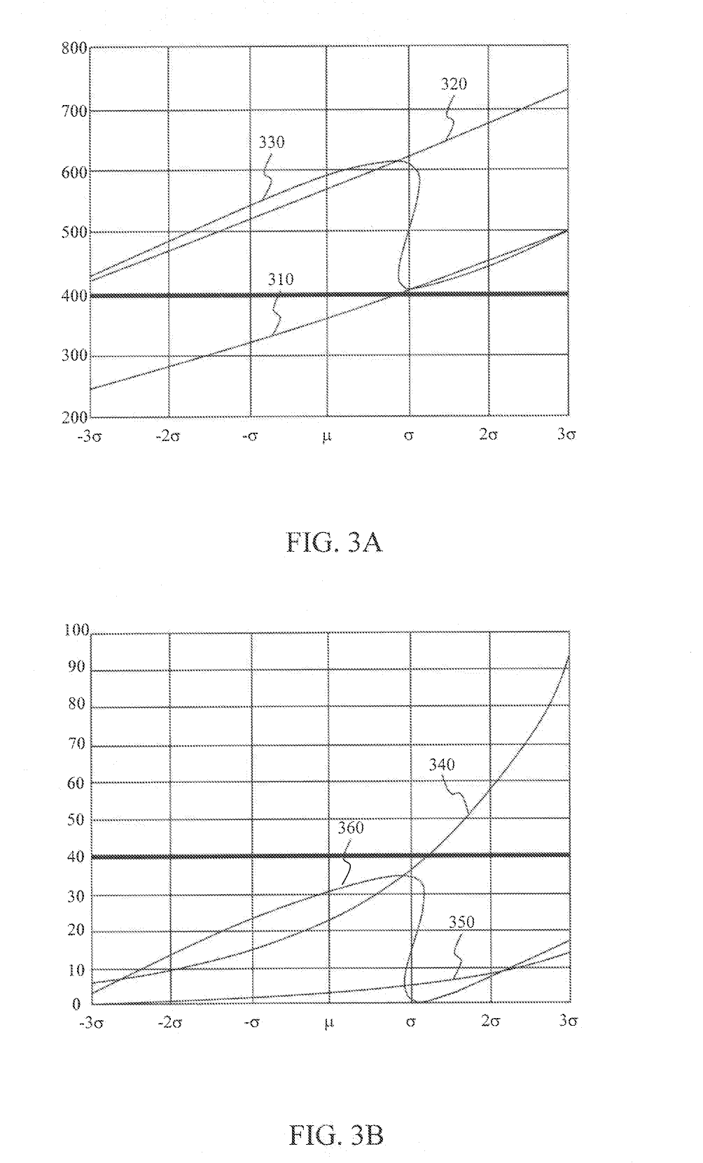

FIGS. 3A and 3B illustrate a first exemplary operation of the first adaptive integrated circuit according to an exemplary embodiment of the present disclosure. An operational speed 310 of the fast semiconductor substrate module 206, an operational speed 320 of the slow semiconductor substrate module 208, and an operational speed 330 of the adaptive integrated circuit 200 are illustrated in a range of three standard deviations of the substrate parameter of the adaptive integrated circuit 200 from its mean μ. As shown in FIG. 3A, the semiconductor substrate upon which the adaptive integrated circuit 200 is fabricated is characterized as being a slow semiconductor substrate when the substrate parameter of the adaptive integrated circuit 200 is measured to be between approximately −3σ and approximately μ and is characterized as being a fast semiconductor substrate when the substrate parameter of the adaptive integrated circuit 200 is measured to be between approximately μ and approximately −3σ.

Typically, the adaptive integrated circuit 200 is specified to operate above a minimum operational frequency, in this case 400 MHz as shown in FIG. 3A, and below a maximum leakage power, in this case 40 mA as shown in FIG. 3B. As additionally shown in FIG. 3A, the adaptive integrated circuit 200 is configured to operate in the slow-mode of operation that corresponds to the operational speed 320 when the substrate parameter of the adaptive integrated circuit 200 is measured to be between approximately −3σ and approximately σ. Although the adaptive integrated circuit 200 can be configured to operate entirely in the slow-mode of operation that corresponds to the operational speed 320 while exceeding the minimum operational frequency, the adaptive integrated circuit 200 is configured to operate in the fast-mode of operation that corresponds to the operational speed 310 once the substrate parameter of the adaptive integrated circuit 200 is measured to be between approximately σ and approximately 3σ. As additionally shown in FIG. 3B, switching from the slow-mode of operation to the fast-mode of operation reduces leakage power of the adaptive integrated circuit 200 such that the leakage power does not exceed the maximum leakage power.

A Second Adaptive Integrated Circuit

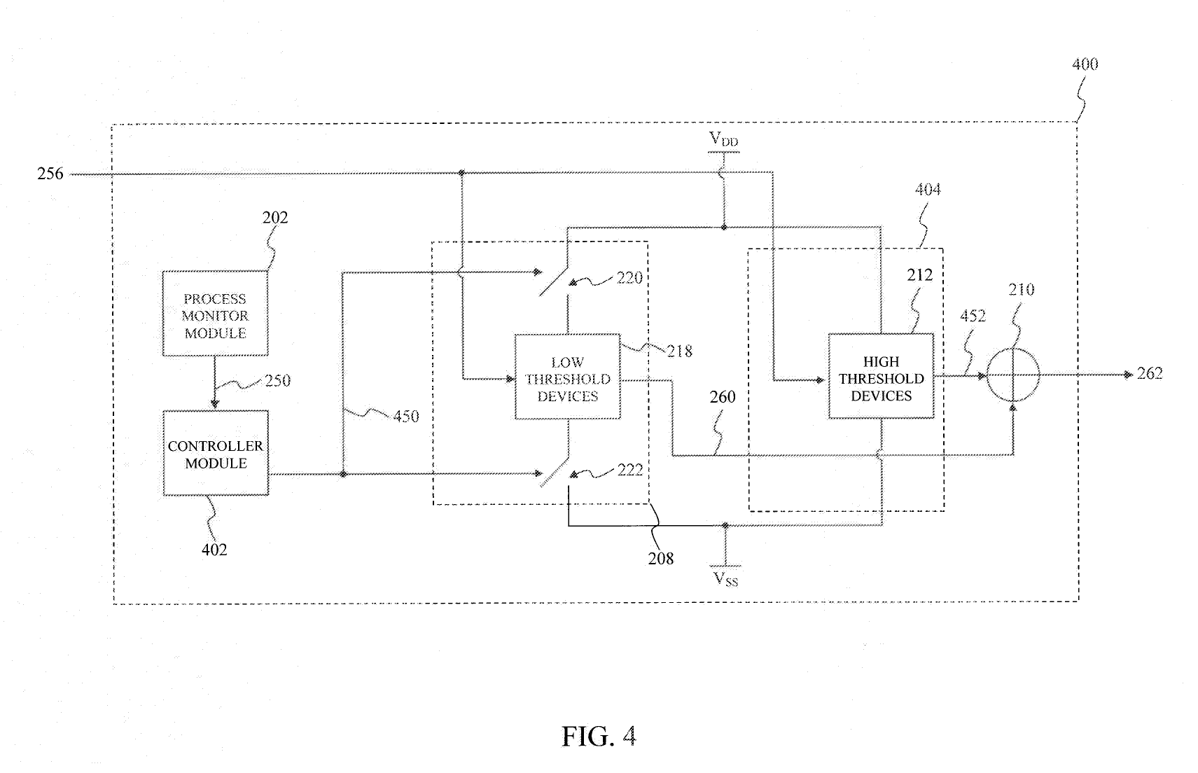

FIG. 4 illustrates a block diagram of a second adaptive integrated circuit according to an exemplary embodiment of the present disclosure. An adaptive integrated circuit 400 is fabricated onto a semiconductor substrate. The adaptive integrated circuit 400 classifies the semiconductor substrate upon which it is fabricated as being a fast semiconductor substrate or a slow semiconductor substrate by monitoring a substrate parameter in a substantially similar manner as the adaptive integrated circuit 200. The adaptive integrated circuit 400 operates in the fast-substrate mode of operation using the low voltage threshold semiconductor devices when the semiconductor substrate is classified as being the fast semiconductor substrate or in the slow-substrate mode of operation when the semiconductor substrate is classified as being the high speed semiconductor substrate in a substantially similar manner as the adaptive integrated circuit 200. The adaptive integrated circuit 400 includes the process monitor module 202, the slow semiconductor substrate module 208, the summation module 210, a controller module 402, and a fast semiconductor substrate module 404. The adaptive integrated circuit 400 is substantially similar to the adaptive integrated circuit 200 in various aspects; therefore only differences between the adaptive integrated circuit 200 and the adaptive integrated circuit 400 are to be described in further detail.

The controller module 402 classifies the semiconductor substrate upon which it is fabricated as being a fast semiconductor substrate or a slow semiconductor substrate based upon the substrate parameter 250 in a substantially similar manner as the controller module 204.

Low-Speed and Fast-Speed Modes of Operation

When the, semiconductor substrate, is classified as being the fast semiconductor substrate, the controller module 204 provides a slow-substrate mode control signal 450 to deactivate the slow semiconductor substrate module 208 to cause the adaptive integrated circuit 200 to operate in the fast-substrate mode of operation. Similarly, when the semiconductor substrate is classified as being the slow semiconductor substrate, the controller module 204 provides the slow-substrate mode control signal 450 to activate the slow semiconductor substrate module 208 to cause the adaptive integrated circuit 200 to operate in the slow-substrate mode of operation.

The fast semiconductor substrate module 404 operates upon the input signal 256 to provide an output signal 452 when the adaptive integrated circuit 200 is operating in the fast-substrate mode of operation that corresponds to the fast semiconductor substrate and the slow-substrate mode of operation that corresponds to the slow semiconductor substrate. In other words, the fast semiconductor substrate module 404 is continuously coupled to the first supply potential, and the second supply potential, namely continuously active. The continuous activeness of the adaptive integrated circuit 400 substantially prevents noise, such as transients to provide an example, from being introduced by the adaptive integrated circuit 400 as well as substantially reduces timing constraints on the adaptive integrated circuit 400 when compared to the adaptive integrated circuit 200. The fast semiconductor substrate module 404 includes the logic circuit that is formed using the high threshold voltage semiconductor devices 212 that is continuously coupled to the first supply potential and the second supply potential.

Exemplary Process Monitor Module that can be Implemented within the First or Second Adaptive Integrated Circuits

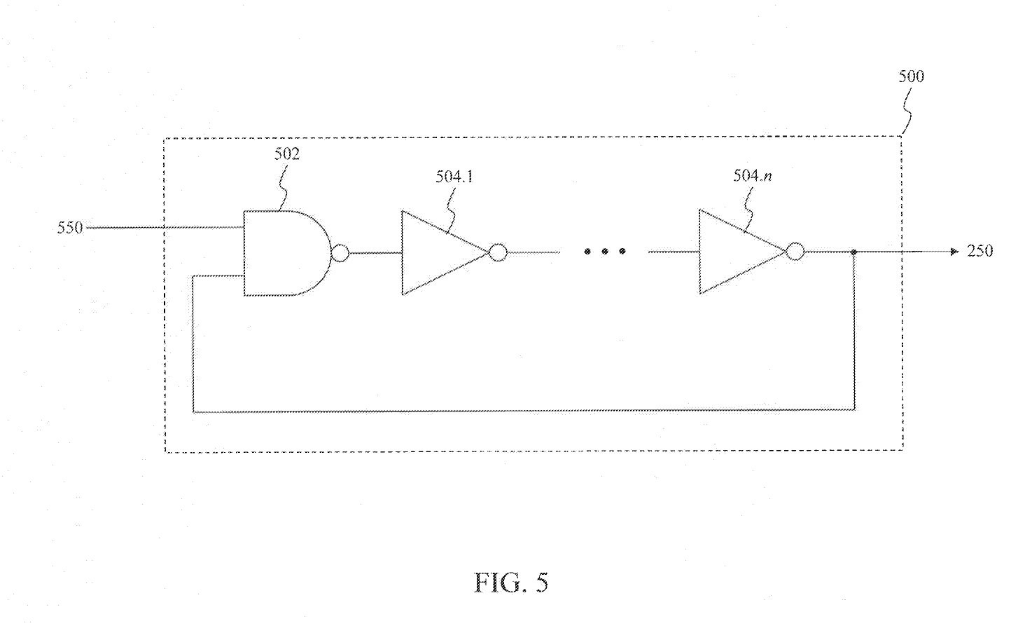

FIG. 5 illustrates a block diagram of an exemplary process monitor module that can be implemented as part of the first or the second adaptive integrated circuits according to an exemplary embodiment of the present disclosure. A process monitor module 500 measures and/or monitors a substrate parameter of an adaptive integrated circuit, such as the adaptive integrated circuit 200 or the adaptive integrated circuit 300 to provide some examples, to provide the substrate parameter 250. The substrate parameter can include an indication of an operational speed of the adaptive integrated circuit. The process monitor module 500 includes a logical NAND gate 502 and logical NOT gates 504.1 through 504.n. The process monitor module 500 can represent an exemplary embodiment of the process monitor module 202.

The logical NAND gate 502 and the logical NOT gates 504.1 through 504.n are configured and arranged to form a ring oscillator. The ring oscillator is controlled by providing an oscillator enable 550 having a first logical value, such as a logical zero to provide an example, to a first input of the logical NAND gate 502. A controller, such as the controller module 204 or the controller module 402 to provide some examples, can be used to provide the oscillator enable 500 to the logical NAND gate 502. Typically, the logical NOT gates 504.1 through 504.n are odd in number such that the substrate parameter 250 will be a second logical value, such as a logical one to provide an example. The substrate parameter 250, in this case the second logical value, is provided to a second input of the logical NAND gate 502 which in turns causes the substrate parameter 250 to be the first logical value to form an oscillating clock signal having an oscillation frequency f_{OSC} as the substrate parameter 250.

The controller measures and/or monitors the substrate parameter 250 to determine the oscillation frequency f_{OSC} of the process monitor module 500. The controller compares the oscillation frequency to various predetermined oscillation frequencies that correspond to expected oscillation frequencies for various semiconductor substrates. For example, as shown in Table 2 below, the controller compares the oscillation frequency f_{OSC} to the expected oscillation frequency f₋₃ through f₃.

TABLE 2
Exemplary Operation of the Controller Module

| | EXPECTED OSCILLATION |
|---|---|
| PROCESS VARIATION | FREQUENCY |
| −3 | f₋₃ |
| −2 | f₋₂ |
| −1 | f₋₁ |
| 0 | f₀ |
| 1 | f₁ |
| 2 | f₂ |
| 3 | f₃ |

Thereafter, the controller module classifies the semiconductor substrate as being the fast semiconductor substrate when the oscillation frequency is closely related to a predetermined oscillation frequency that corresponds to an expected oscillation frequency for the fast semiconductor substrate or as being the slow semiconductor substrate when the oscillation frequency is closely related to a predetermined oscillation frequency that corresponds to an expected oscillation frequency for the slow semiconductor substrate. For example, referring back to Table 2, the controller determines that the oscillation frequency f_{OSC} is closer to one of the expected oscillation frequencies f₋₃ through f₃ which corresponds to one of the process variations −3 through 3. In Table 2, the process variations −3 through 3 correspond to the number of standard deviations that their corresponding expected oscillation frequency f₋₃ through f₃ is away from the expected oscillation frequency f₋₀, namely an expected oscillation frequency of the process monitor module 500. In this example, the controller classifies the semiconductor substrate as being the slow semiconductor substrate when the oscillation frequency f_{OSC} corresponds to process variations −3 through 0, the fast semiconductor substrate when the oscillation frequency f_{OSC} corresponds to process variations 0 through 3, or the semiconductor substrate as being the slow semiconductor substrate or the fast semiconductor substrate when the oscillation frequency f_{OSC} corresponds to process variation 0.

### Conclusion

It is to be appreciated that the Detailed Description section, and not the Abstract section, is intended to be used to interpret the claims. The Abstract section may set forth one or more, but not all exemplary embodiments, of the present disclosure, and thus, are not intended to limit the present disclosure and the appended claims in any way.

The present disclosure has been described above with the aid of functional building blocks illustrating the implementation of specified functions and relationships thereof. The boundaries of these functional building blocks have been arbitrarily defined herein for the convenience of the description. Alternate boundaries may be defined so long as the specified functions and relationships thereof are appropriately performed.

It will be apparent to those skilled in the relevant art(s) that various changes in form and detail can be made therein without departing from the spirit and scope of the disclosure. Thus the present disclosure should not be limited by any of the above-described exemplary embodiments, but should be defined only in accordance with the following claims and their equivalents.

What is claimed is:

1. An adaptive integrated circuit, comprising:
a substrate;
a process monitor configured to measure a substrate parameter of the substrate;
a controller module configured to classify the semiconductor substrate as being a fast semiconductor substrate or a slow semiconductor substrate based upon the substrate parameter;
a fast semiconductor substrate module, including a first logic circuit that is formed using high threshold voltage semiconductor devices, configured to be active when the semiconductor substrate is classified as being the fast semiconductor substrate; and
a slow semiconductor substrate module, including a second logic circuit that is formed using low threshold voltage semiconductor devices, configured to be active when the semiconductor substrate is classified as being the slow semiconductor substrate.

2. The adaptive integrated circuit of claim 1, wherein the processor monitor comprises:
a ring oscillator configured to provide an oscillating clock signal having an oscillation frequency as the substrate parameter.

3. The adaptive integrated circuit of claim 1, wherein the controller module is further configured to:
determine an expected substrate parameter from among a plurality of expected substrate parameters that corresponds to an actual value of the substrate parameter;
mapping the expected substrate parameter to a corresponding standard deviation from a plurality of standard deviations;
classify the semiconductor substrate as being the slow semiconductor substrate when the corresponding standard deviation is less than zero, as being the fast semiconductor substrate when the corresponding standard deviation is greater than zero, or as being either the slow or the fast semiconductor substrate when the corresponding standard deviation is equal to zero.

4. The adaptive integrated circuit of claim 1, wherein the second logic circuit is configured to perform a substantially similar signal processing function as the first logic circuit.

5. The adaptive integrated circuit of claim 1, wherein the fast semiconductor substrate module is further configured to be inactive when the semiconductor substrate is classified as being the slow semiconductor substrate, and
wherein the slow semiconductor substrate module is further configured to be inactive when the semiconductor substrate is classified as being the last semiconductor substrate.

6. The adaptive integrated circuit of claim 1, wherein the controller module is further configured to provide a fast-substrate mode control signal to couple the fast semiconductor substrate module to at least one supply potential to activate the fast semiconductor substrate module when the semiconductor substrate is classified as being the fast semiconductor substrate, and
wherein the controller module is further configured to provide a slow-substrate mode control signal to couple the slow semiconductor substrate module to the at least one supply potential to activate the slow semiconductor substrate module when the semiconductor substrate is classified as being the slow semiconductor substrate.

7. The adaptive integrated circuit of claim 6, wherein the controller module is further configured to provide the fast-substrate mode control signal to decouple the fast semiconductor substrate module from the at least one supply potential to deactivate the fast semiconductor substrate module when the semiconductor substrate is classified as being the slow semiconductor substrate, and
wherein the controller module is further configured to provide the slow-substrate mode control signal to decouple the slow semiconductor substrate module from the at least one supply potential to deactivate the fast semiconductor substrate module when the semiconductor substrate is classified as being the fast semiconductor substrate.

8. The adaptive integrated circuit of claim 1, wherein the high threshold voltage semiconductor devices are characterized as having a lower operating speed and a lesser leakage current when compared to the low threshold voltage semiconductor devices.

9. An adaptive integrated circuit formed onto a substrate, comprising:
a controller module configured to classify the semiconductor substrate as being a fast semiconductor substrate or a slow semiconductor substrate;
a fast semiconductor substrate module including a high threshold voltage semiconductor device that is configured to continuously process an input signal; and
a slow semiconductor substrate module including a low threshold voltage semiconductor device that is configured to process the input signal only when the semiconductor substrate is classified as being the slow semiconductor substrate.

10. The adaptive integrated circuit of claim 9, further comprising:
a process monitor configured to measure a substrate parameter of the substrate,
wherein the controller module is further configured to classify the semiconductor substrate based upon the substrate parameter.

11. The adaptive integrated circuit of claim 9, wherein the slow semiconductor substrate module comprises:
a first and a second activation switch coupled to a first and a second supply potential, respectively; and
a logic circuit, coupled between the first and second activation switches, formed using the low threshold voltage semiconductor device,
wherein the controller module is configured to activate the first and second activation switches only when the semiconductor substrate is classified as being the slow semiconductor substrate.

12. The adaptive integrated circuit of claim 9, wherein the slow semiconductor substrate module and the fast semiconductor substrate module are configured to process the input signal in accordance with substantially similar signal processing functions using the low threshold voltage semiconductor device and the high threshold voltage semiconductor device, respectively.

13. The adaptive integrated circuit of claim 9, wherein the slow semiconductor substrate module is further configured to be inactive when the semiconductor substrate is classified as being the fast semiconductor substrate.

14. The adaptive integrated circuit of claim 9, wherein the controller module is further configured to provide a slow-substrate mode control signal to couple the slow semiconductor substrate module to at least one supply potential to activate the slow semiconductor substrate module when the semiconductor substrate is classified as being the slow semiconductor substrate or to decouple the slow semiconductor substrate module from the at least one supply potential to deactivate the slow semiconductor substrate module when the semiconductor substrate is classified as being the fast semiconductor substrate.

15. An adaptive integrated circuit, comprising:
a controller module configured to cause the adaptive integrated circuit to operate in a fast-substrate mode of operation or in a slow-substrate mode of operation;
a fast semiconductor substrate module, including a first logic circuit that is formed using high threshold voltage semiconductor devices, configured to be active in the fast-substrate mode of operation; and
a slow semiconductor substrate module, including a second logic circuit that is formed using low threshold voltage semiconductor devices, configured to be active in the slow-substrate mode of operation.

16. The adaptive integrated circuit of claim 15, wherein the fast semiconductor module is further configured to be active in the slow-substrate mode of operation.

17. The adaptive integrated circuit of claim 15, wherein the fast semiconductor substrate module is characterized as having a lower operating speed and a lesser leakage current when compared to the slow semiconductor substrate module.

18. The adaptive integrated circuit of claim 15, wherein the controller is configured to cause the adaptive integrated circuit to operate in the fast-substrate mode of operation when an operational frequency of the adaptive integrated circuit is above a minimum operational frequency and a leakage power of the adaptive integrated circuit is below a maximum leakage power or to operate in the slow-substrate mode of operation when the operational frequency is below the minimum operational frequency or the, leakage power is above the maximum leakage power.

19. The adaptive integrated circuit of claim 15, wherein the slow semiconductor substrate module comprises:
a first and, a second activation switch coupled to a first and a second supply potential, respectively; and
a first logic circuit, coupled between the first and second activation switches, formed using the low threshold voltage semiconductor devices, wherein the controller module is configured to activate the first and second activation switches when in the slow-substrate mode of operation.

20. The adaptive integrated circuit of claim 19, wherein the fast semiconductor substrate module comprises:
a third and a fourth activation switch coupled to the first and the second supply potential, respectively; and
a second logic circuit, coupled between the first and second activation switches, formed using the high threshold voltage semiconductor devices and configured to perform a substantially similar signal processing function as the first logic circuit,
wherein the controller module is configured to activate the third and fourth activation switches when in the fast-substrate mode of operation.
